(19) United States
(12) Patent Application Publication
(10) Pub. No.: US 2025/0233034 A1
(43) Pub. Date: Jul. 17, 2025

(54) SEMICONDUCTOR STRUCTURE WITH CAPPING LAYER AND MANUFACTURING METHOD THEREOF

(71) Applicant: Taiwan Semiconductor Manufacturing Company, Ltd., Hsinchu (TW)

(72) Inventors: Hung-Pin Chang, New Taipei City (TW); Cheng-Hsien Hsieh, Kaohsiung City (TW); Han-Yi Lu, Hsinchu City (TW); Li-Han Hsu, Hsin-Chu City (TW); Wei-Cheng Wu, Hsinchu City (TW); Der-Chyang Yeh, Hsin-Chu (TW)

(73) Assignee: Taiwan Semiconductor Manufacturing Company, Ltd., Hsinchu (TW)

(21) Appl. No.: 18/415,487

(22) Filed: Jan. 17, 2024

(51) Int. Cl. H01L 23/31; H01L 23/00; H01L 23/498; H01L 25/00; H01L 25/065

(52) U.S. Cl. CPC H01L 23/31; H01L 23/49838; H01L 24/16; H01L 24/32; H01L 24/73; H01L 25/0657; H01L 25/50; H01L 2224/16225; H01L 2224/32145; H01L 2224/32225; H01L 2224/73204; H01L 2924/181

(57) ABSTRACT

A semiconductor structure includes a first semiconductor die and a second semiconductor die stacked upon and bonded to one another, a capping layer sealing a bonding interface of the first and second semiconductor dies, and an insulating encapsulant disposed over the second semiconductor die and covering the first semiconductor die and the capping layer. The first semiconductor die includes a first portion and a second portion connected to the first portion, and the first portion is wider than the second portion.

### BACKGROUND

The semiconductor industry has experienced rapid growth due to continuous improvement in integration density of various components, e.g., transistors, diodes, resistors, capacitors, etc. For the most part, this improvement in integration density has come from successive reductions in minimum feature size, which allows more components to be integrated into a given area. Technological advances in integrated circuit (IC) design have produced generations of ICs where each generation has smaller and more complex circuit designs than the previous generation. There is continuous effort in developing new mechanisms of forming semiconductor structures having improved electrical performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1C illustrate schematic cross-sectional views of intermediate steps during a process for forming a first semiconductor die, in accordance with some embodiments.

FIG. 2A through FIG. 2D illustrate schematic cross-sectional views of intermediate steps during a process for forming a semiconductor structure, in accordance with some embodiments.

FIG. 2E illustrates a schematic top view of a semiconductor structure, in accordance with some embodiments.

FIG. 3 illustrates schematic a cross-sectional view of an integrated circuit package including a semiconductor structure, in accordance with some embodiments.

FIG. 4A and FIG. 4B illustrate schematic cross-sectional views of intermediate steps during a process for forming a semiconductor structure, in accordance with some embodiments.

FIG. 5A and FIG. 5B illustrate schematic cross-sectional views of intermediate steps during a process for forming a first semiconductor die, in accordance with some embodiments.

FIG. 6A and FIG. 6B illustrate schematic cross-sectional views of intermediate steps during a process for forming a semiconductor structure, in accordance with some embodiments.

FIG. 7A and FIG. 7B illustrate schematic cross-sectional views of intermediate steps during a process for forming a semiconductor structure, in accordance with some embodiments.

FIG. 8 illustrates a schematic cross-sectional view of a semiconductor structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein are to provide various semiconductor structures and methods for forming the same. For example, a semiconductor structure is formed by bonding a first semiconductor die to a second semiconductor die, forming a capping layer to seal the bonding interface of the first and second semiconductor dies, and forming an insulating encapsulant on the second semiconductor die to surround the first semiconductor die and the capping layer. The internal stress originates from a difference in thermal expansion among the first and second semiconductor dies and the insulating encapsulant. The thermal expansion difference is because a difference in a coefficient of thermal expansion (CTE) of the materials among the first and second semiconductor dies and the insulating encapsulant. In addition, the large CTE mismatch among the insulating encapsulant and the first and second semiconductor dies generates the stress in the semiconductor structure, especially at the bonding interface of the first and second semiconductor dies. Delamination of bonding dielectric layers in the bonded structure may occur or become worse during the formation of the insulating encapsulant. For example, the delamination propagates from a non-functional (or peripheral) region of the bonded structure toward a functional (or central) region of the bonded structure and such propagation may cause device failure. By forming the capping layer to surround the bonding interface, the capping layer may serve as a seal between the first and second semiconductor dies. The presence of the capping layer may help to reduce the risk of delamination propagation during the formation of the insulating encapsulant. Accordingly, a semiconductor structure with reduced defects, improved reliability, and improved yield may be achieved.

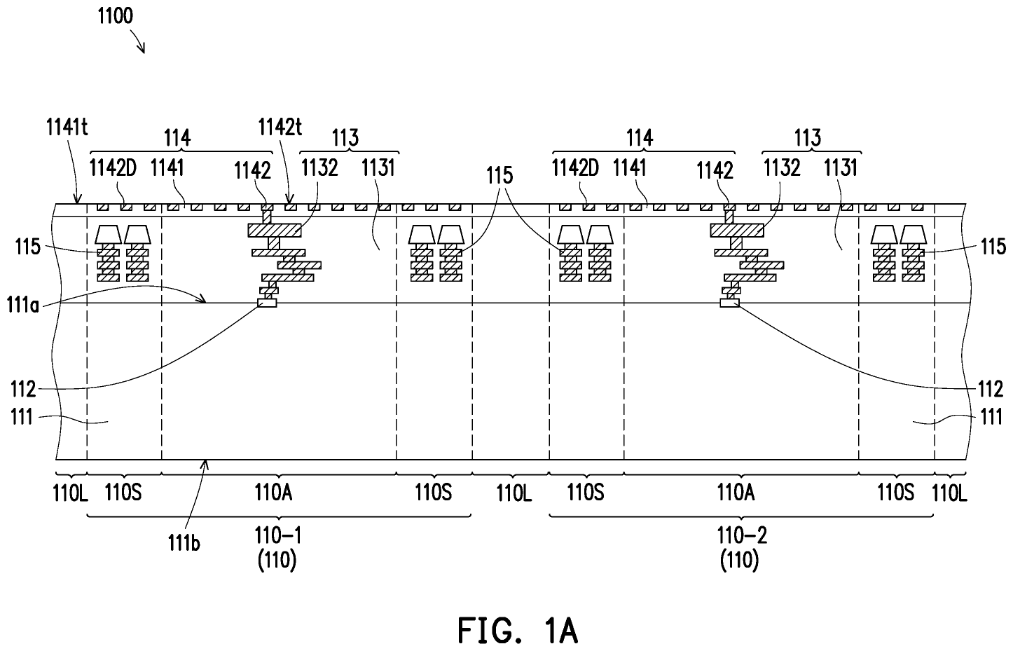

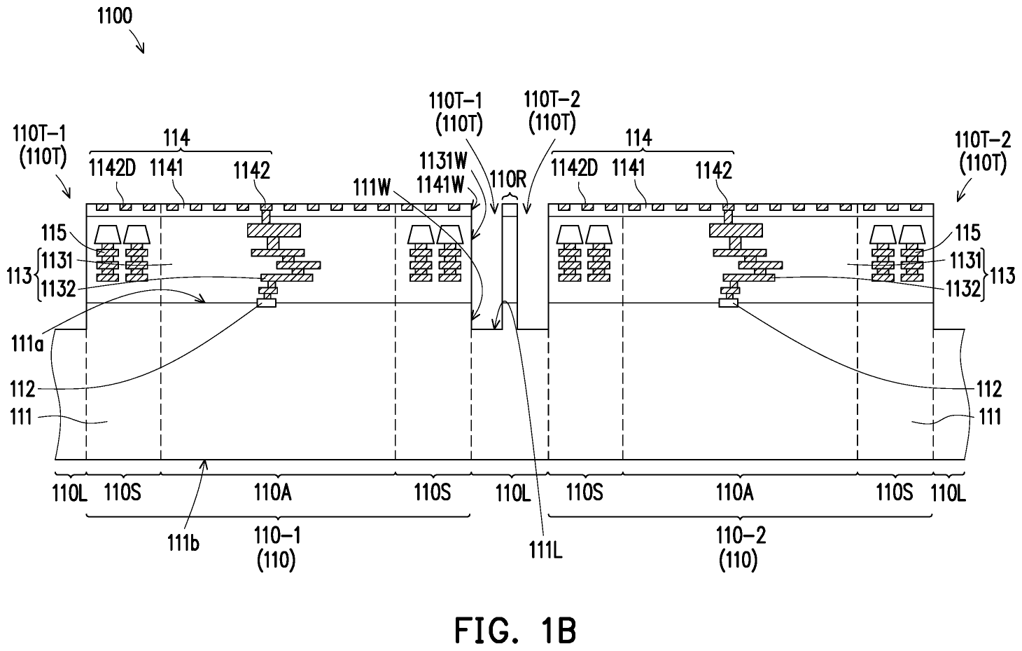

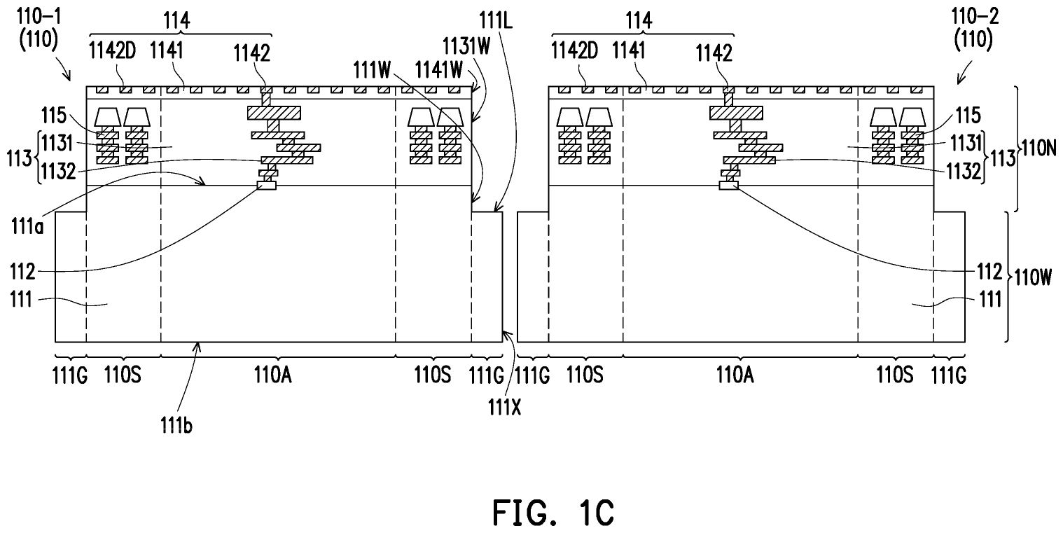

FIG. 1A through FIG. 1C illustrate schematic cross-sectional views of intermediate steps during a process for forming a first semiconductor die, in accordance with some embodiments. It should be noted that FIGS. 1A and 1B are provided for illustrative purposes only, and the first semiconductor die may utilize fewer or additional elements according to some embodiments.

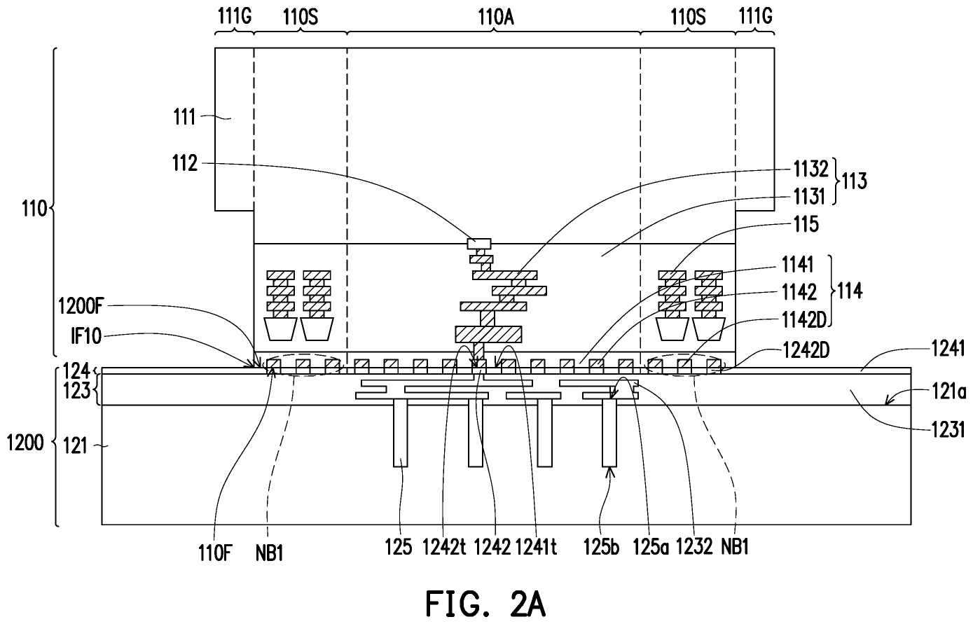

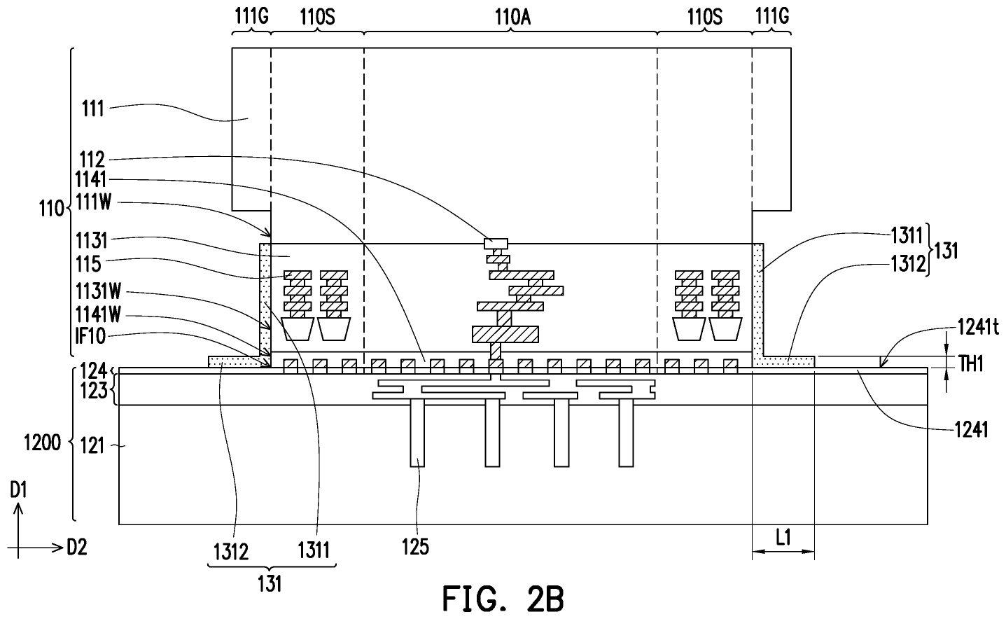

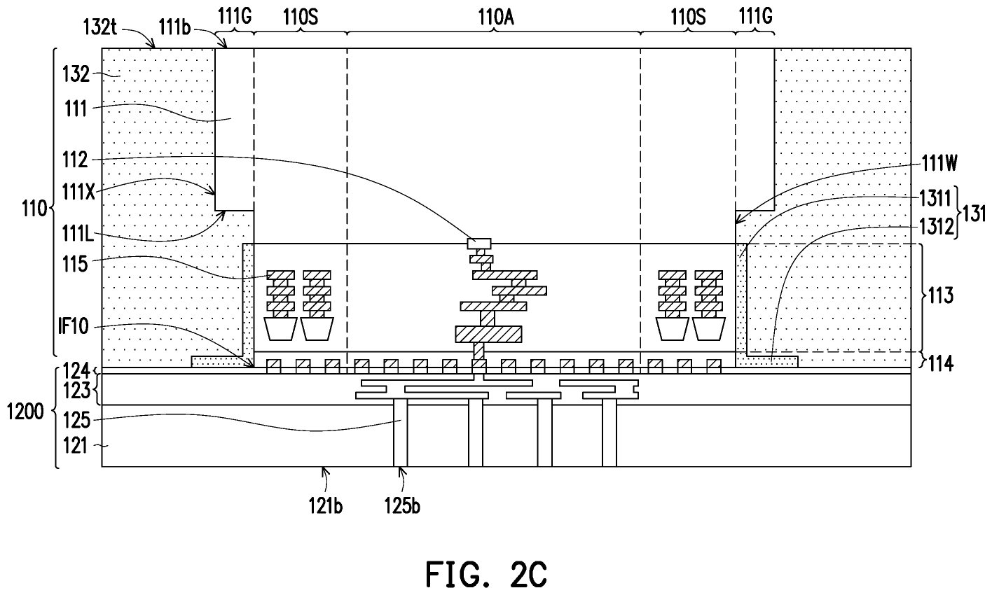

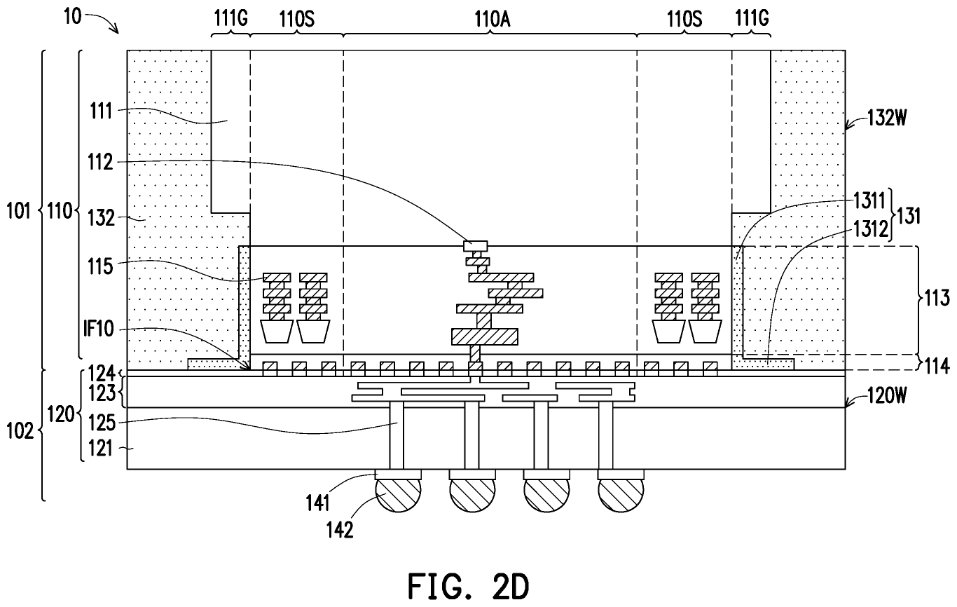

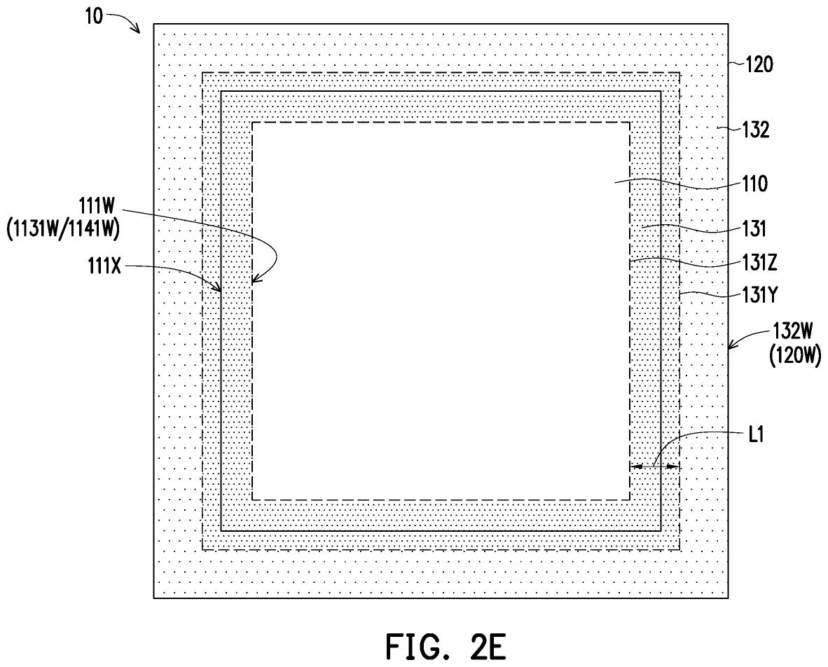

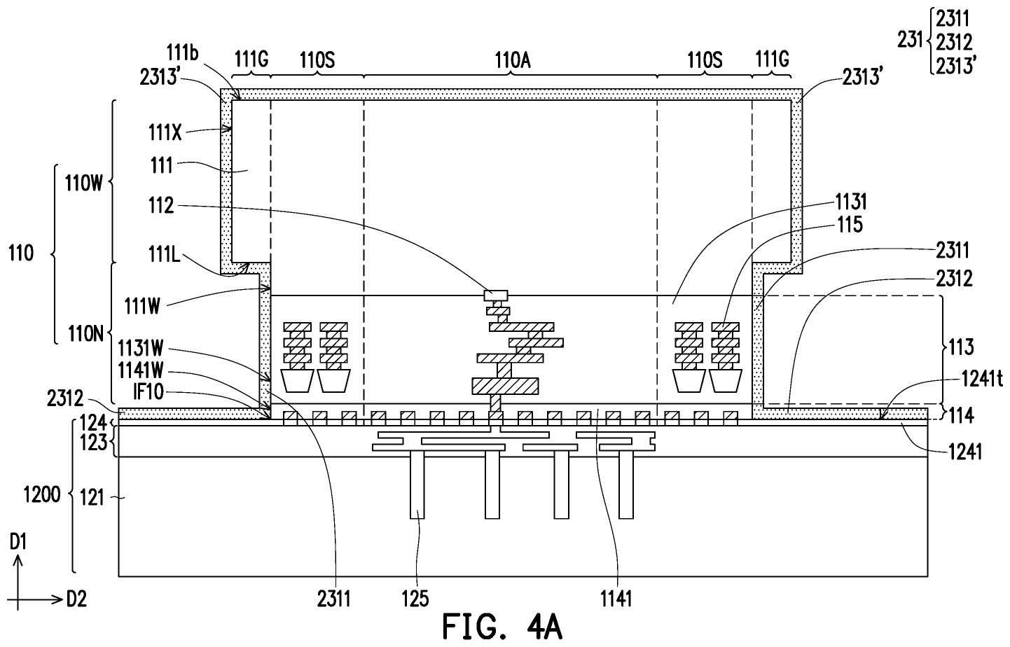

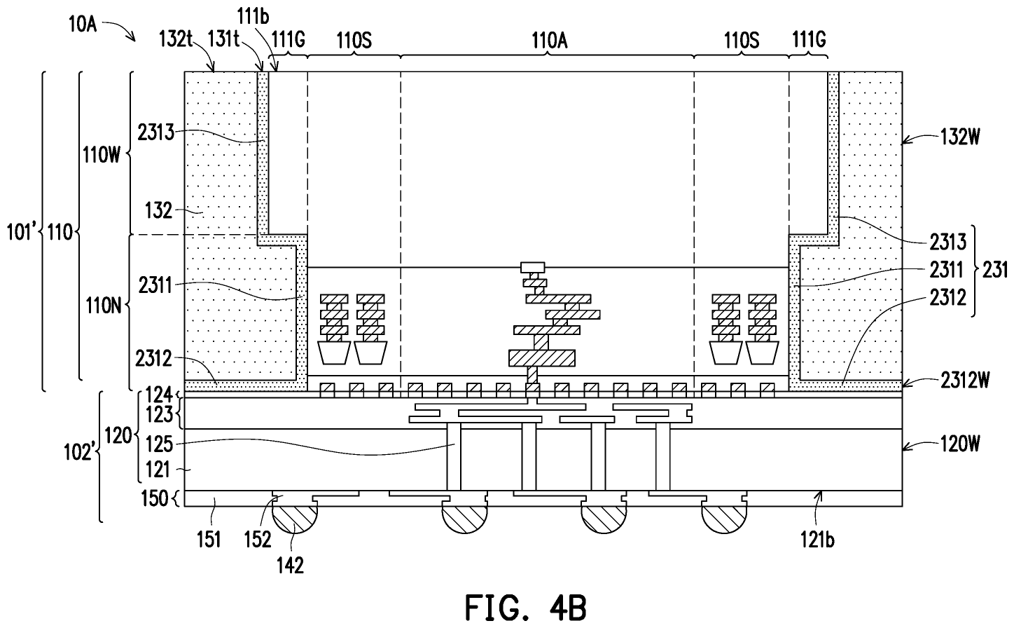

Referring to FIG. 1A, a semiconductor wafer 1100 including a plurality of die regions (e.g., 110-1, 110-2) is provided. The die regions (e.g., 110-1, 110-2) may be separated by scribe line regions 110L in which the subsequent singulation process is performed. For example, the die regions (e.g., 110-1, 110-2) are singulated to form individual first semiconductor dies 110, where the respective first semiconductor die 110 may be included in a first tier of the resulting semiconductor structure (e.g., see FIG. 2D FIG. 4B). The respective first semiconductor die 110 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), combinations thereof (e.g., a system-on-a-chip (SoC) die), or the like.

In some embodiments, the respective first semiconductor die 110 includes a first semiconductor substrate 111, first devices 112 formed in/on the first semiconductor substrate 111, a first interconnect structure 113 formed over the first semiconductor substrate 111 and electrically coupled to the first devices 112, and a first bonding structure 114 formed over and electrically coupled to the first interconnect structure 113. The first semiconductor substrate 111 may be a substrate of silicon, doped or undoped, or an active layer of a semiconductor-on-insulator (SOI) substrate. The first semiconductor substrate 111 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other suitable substrate, such as a multi-layered substrate or a gradient substrate, may be used.

The first semiconductor substrate 111 may include a front side 111a and a back side 111b opposite to the front side 111a. For example, the first devices 112 are formed at the front side 111a of the first semiconductor substrate 111. The first devices 112 may include active devices (e.g., transistors, diodes, etc.), passive devices (e.g., capacitors, resistors, inductors, etc.), a combination thereof, or the like. Although a single first device 112 is schematically illustrated in the respective first semiconductor die 110, it should be noted that the number and the type of the first device 112 may have a different number and type than shown.

With continued reference to FIG. 1A, the first interconnect structure 113 may be formed over the front side 111a of the first semiconductor substrate 111 and may be electrically coupled to the first devices 112 to form integrated circuits. The first interconnect structure 113 may include one or more first dielectric layer(s) 1131 and first metallization patterns 1132 embedded in the first dielectric layer 1131. The material of the first dielectric layer 1131 may include an oxide (e.g., silicon oxide or aluminum oxide), a nitride (e.g., silicon nitride), a carbide (e.g., silicon carbide), the like, or combinations thereof. The respective first metallization pattern 1132 may include conductive pads, conductive lines, conductive vias, combinations thereof, and/or the like. The respective first metallization pattern 1132 may be formed of a conductive material such as copper, cobalt, aluminum, gold, combinations thereof, or the like. It should be noted that the first dielectric layer 1131 and the first metallization patterns 1132 may have a different configuration than shown.

In some embodiments, the first bonding structure 114 includes one or more first bonding dielectric layer(s) 1141 and first bonding connectors 1142 embedded in the first bonding dielectric layer 1141. The first bonding dielectric layer 1141 may be formed of a material suitable for subsequent dielectric-to-dielectric bonding, such as, silicon oxide, silicon oxynitride, and/or the like. The first bonding connectors 1142 may be formed of a conductive material such as copper, aluminum, or the like. The respective first bonding connector 1142 may be a conductive pad, a conductive via, a combination thereof, etc. In some embodiments, the first bonding connectors 1142 are electrically connected to the first metallization patterns 1132 of the first interconnect structure 113. It should be noted that the first bonding dielectric layer 1141 and the first bonding connectors 1142 may have a different configuration than shown. In some embodiments, a planarization process (e.g., a chemical mechanical polish (CMP) process, a grinding process, an etching process, a combination thereof, or the like) is performed such that top surfaces (1141t and 1142t) of the first bonding dielectric layer 1141 and the first bonding connectors 1142 are substantially leveled (or coplanar), within process variations.

With continued reference to FIG. 1A, the respective first semiconductor die 110 includes a functional (or active) region 110A and a seal ring region 110S surrounding the functional region 110A. For example, the seal ring region 110S is between the functional region 110A and the scribe line region 110L, and the scribe line region 110L is between two adjacent die regions (e.g., 110-1, 110-2). In some embodiments, the first devices 112, the first metallization patterns 1132, and the first bonding connectors 1142 are located within the functional region 110A. In some embodiments, both of the first bonding dielectric layer 1141 and the first dielectric layer 1131 extend across the functional region 110A and the seal ring region 110S, as well as the scribe line region 110L. The respective first semiconductor die 110 may (or may not) include conductive features within the scribe line region 110L.

In some embodiments, one or more seal ring(s) 115 may be formed in the first dielectric layer 1131 and within the seal ring region 110S. For example, the seal rings 115 are disposed in the peripheral region of each first semiconductor die 110. In some embodiments, the respective seal ring 115 is disposed in a loop encircling first metallization patterns 1132 in the functional region 110A. The seal rings 115 may include conductive vias and conductive pads vertically stacked and connected together by the conductive vias, where the conductive pads of the seal rings 115 may be at a same level as the conductive pads of the first metallization patterns 1132, and the conductive vias of the seal rings 115 may be at the same level as the conductive vias of the first metallization patterns 1132. The respective first semiconductor die 110 may (or may not) include any metallization patterns and/or conductive features outside of the seal rings 115. It should be noted that the seal rings 115 may have a different configuration than shown.

Still referring to FIG. 1A, the first bonding structure 114 may include additional bonding connectors 1142D embedded in the first bonding dielectric layer 1141 and formed over the seal rings 115 within the seal ring region 110S. The additional bonding connectors 1142D may be formed at the same level as the first bonding connectors 1142. In some embodiments, the additional bonding connectors 1142D are electrically and spatially isolated from the seal rings 115 at least through the first bonding dielectric layer 1141. In alternative embodiments, the additional bonding connectors 1142D are physically connected to the underlying seal rings 115. In some embodiments, the additional bonding connectors 1142D are dummy connectors and electrically floating in the respective first semiconductor die 110. For example, the presence of the additional bonding connectors 1142D helps to increase the pattern uniformity and metal density, thereby facilitating the subsequent bonding process. Alternatively, the additional bonding connectors 1142D are omitted, and no conductive features are formed directly over the seal ring 115.

Referring to FIG. 1B and with reference to FIG. 1A, trenches 110T may be optionally formed in the semiconductor wafer 1100 within the scribe line regions 110L between adjacent die regions (e.g., 110-1, 110-2). In some embodiments, the trenches 110T are formed by an etching process (e.g., a dry etch process, such as reactive ion etching or the like), a plasma dicing process, or the like. The respective trench 110T may extend through the first bonding dielectric layer 1141 and the first dielectric layer 1131. In some embodiments, the respective trench 110T further extends into the first semiconductor substrate 111. The respective trench 110T may not penetrate through the first semiconductor substrate 111. For example, the respective trench 110T is defined by a sidewall 1141W of the first bonding dielectric layer 1141, a sidewall 1131W of the first dielectric layer 1131, a sidewall 111W of the first semiconductor substrate 111, and a lower surface 111L of the first semiconductor substrate 111. For example, the lower surface 111L of the first semiconductor substrate 111 is between the front side 111a and the back side 111b.

In some embodiments, the respective trench 110T is formed as a loop encircling the corresponding die regions (e.g., 110-1, 110-2). For example, the die region 110-1 is encircled by the trench 110T-1, while the die region 110-2 is encircled by the trench 110T-2. The trench 110T-1 and the trench 110T-2 may not be in communication with each other. For example, the trench 110T-1 and the trench 110T-2 are spatially separated from each other by a ridge portion 110R within the scribe line region 110L. The ridge portion 110R may include remaining portions of the first bonding dielectric layer 1141, the first dielectric layer 1131, and the first semiconductor substrate 111 which are left in the scribe line region 110L and between the two adjacent trenches (110T-1 and 110T-2).

Referring to FIG. 1C and with reference to FIG. 1B, a sawing process may be performed on the semiconductor wafer 1100 to separate the die regions (e.g., 110-1, 110-2) from one another, thereby forming individual first semiconductor dies 110. The sawing process may be performed through the trenches 110T in the scribe line regions 110L. In some embodiments, the sawing process is a mechanical process using a saw blade that is placed in the adjacent trenches (110T-1 and 110T-2) to saw through the ridge portion 110R. Other sawing processes may be used in other embodiments. In some embodiments, a portion of the first semiconductor substrate 111 in the ridge portion 110R remains after the sawing process, and thus the first semiconductor substrate 111 having a ledge portion 111G is formed. The lateral dimension (e.g., the width) of the ledge portion 111G may vary and may depend on the width of the blade which is used to perform the sawing process. It is noted that the width of the ledge portion 111G construes no limitation in the disclosure. The sidewall 111X of the ledge portion 111G may be formed through the sawing process. Due to differences in the etching process and the sawing process, sidewalls/surfaces of different regions of the respective first semiconductor die 110 may have different roughness. For example, the sidewalls (111W, 1131W, and 1141W) formed by etching (or plasma dicing) is smoother than the sidewall 111X formed by sawing. In some embodiments, a surface roughness of the sidewalls (111W, 1131W, and 1141W) is less than that of the sidewall 111X.

As shown in FIG. 1C, the respective first semiconductor die 110 may include a first portion 110W and a second portion 110N connected to the first portion 110W, where the first portion 110W is a part of the first semiconductor substrate 111, and the second portion 110N includes the other part of the first semiconductor substrate 111 and the overlying structure on the other part of the first semiconductor substrate 111. The first portion 110W may be laterally protruded from the second portion 110N. For example, the sidewall (i.e. 111X) of the first portion 110W is laterally displaced from the sidewalls (including 111W, 1131W, and 1141W) of the second portion 110N. The first portion 110W may be wider than the second portion 110N. For example, the difference between the lateral dimensions of the first portion 110W and the second portion 110N is the lateral dimension of the ledge portion 111G. In some embodiments, the presence of the ledge portion 111G helps to avoid stress concentration on the periphery of the bonding interface during the formation of the insulating encapsulant (see FIG. 2C).

FIG. 2A through FIG. 2D illustrate schematic cross-sectional views of intermediate steps during a process for forming a semiconductor structure 10, and FIG. 2E illustrates a schematic top view of the semiconductor structure, in accordance with some embodiments. The first semiconductor die 110 described in FIG. 1C may be included in a first tier 101 of the semiconductor structure 10 (see FIG. 2D), and the first semiconductor die 110 may be used to electrically connect another tier to form the semiconductor structure 10, as will be discussed in greater detail below. Like reference numerals denote like features with similar structures and compositions.

Referring first to FIG. 2A, a semiconductor wafer 1200 may be provided. The semiconductor wafer 1200 may include a second semiconductor substrate 121, a second interconnect structure 123 formed over the second semiconductor substrate 121, a second bonding structure 124 formed over the second interconnect structure 123, and through vias 125 in the second semiconductor substrate 121 and extending into the second interconnect structure 123. The second semiconductor substrate 121 may be a bulk semiconductor substrate, a SOI substrate, a multi-layered semiconductor substrate, or the like. The material of the second semiconductor substrate 121 may be selected from the same group of candidate materials for forming the first semiconductor substrate 111 discussed in FIG. 1A. The second semiconductor substrate 121 may be doped or undoped. In some embodiments, the semiconductor wafer 1200 is free of active/passive devices, and the second semiconductor substrate 121 does not include devices formed at a front side 121a of the second semiconductor substrate 121. In some embodiments, active devices (e.g., transistors, diodes, etc.) and/or passive devices (e.g., capacitors, resistors, inductors, etc.) are formed at the front side 121a of the second semiconductor substrate 121.

The second interconnect structure 123 may be formed over the front side 121a of the second semiconductor substrate 121. The second interconnect structure 123 may include one or more second dielectric layer(s) 1231 and second metallization patterns 1232 embedded in the second dielectric layer 1231. The second dielectric layer 1231 and the second metallization patterns 1232 may be respectively similar to the first dielectric layer 1131 and the first metallization patterns 1132 which are described in FIG. 1A, and thus the details thereof are not repeated herein. The second bonding structure 124 may be formed over and electrically connected to the second interconnect structure 123. For example, the second bonding structure 124 includes one or more second bonding dielectric layer(s) 1241 and second bonding connectors 1242 embedded in the second bonding dielectric layer 1241. The second bonding connectors 1242 may be electrically connected to the second metallization patterns 1232. The second bonding dielectric layer 1241 and the second bonding connectors 1242 may be respectively similar to the first bonding dielectric layer 1141 and the first bonding connectors 1142 which are described in FIG. 1A, and thus the details thereof are not repeated herein. In some embodiments, a planarization process (e.g., a CMP process, a grinding process, an etching process, a combination thereof, or the like) is performed such that top surfaces (1241t and 1242t) of the second bonding dielectric layer 1241 and the second bonding connectors 1242 are substantially leveled (or coplanar), within process variations.

With continued reference to FIG. 2A, the second bonding structure 124 may include additional bonding connectors 1242D embedded in the second bonding dielectric layer 1241. The additional bonding connectors 1242D may be formed at the same level as the second bonding connectors 1242. In some embodiments, the additional bonding connectors 1242D are dummy connectors and electrically isolated from the second bonding connectors 1242. The additional bonding connectors 1242D may be electrically floating in the semiconductor wafer 1200. In some embodiments, the additional bonding connectors 1242D are subsequently bonded to the additional bonding connectors 1142D of the first semiconductor die 110. The through vias 125 may be formed in the second semiconductor substrate 121 by depositing one or more diffusion barrier layer(s) or isolation layer(s), depositing a seed layer, and depositing a conductive material (e.g., tungsten, titanium, aluminum, copper, any combinations thereof and/or the like) into the trenches of the second semiconductor substrate 121. For example, the respective through via 125 includes a first end 125a physically and electrically connected to one of the second metallization patterns 1232 and a second end 125b opposite to the first end 125a, where the second end 125b may be buried in the second semiconductor substrate 121 at this stage.

Still referring to FIG. 2A and with reference to FIG. 1C, the first semiconductor die 110 may be bonded to the semiconductor wafer 1200. It should be noted that although a single first semiconductor die 110 is illustrated, any number of the first semiconductor dies 110 may be bonded to the semiconductor wafer 1200. In some embodiments, the first semiconductor die 110 and the semiconductor wafer 1200 are directly bonded in a face-to-face manner by dielectric-to-dielectric bonding and metal-to-metal bonding, such that the front side 110F of the first semiconductor die 110 is bonded to the front side 1200F of the semiconductor wafer 1200. For example, the first bonding dielectric layer 1141 is fused to the second bonding dielectric layer 1241 through dielectric-to-dielectric bonding, and dielectric-to-dielectric (e.g., oxide-to-oxide) bonds may be formed therebetween. The first bonding connectors 1142 may be bonded to the second bonding connectors 1242 through metal-to-metal bonding, and metal-to-metal (e.g., copper-to-copper) bonds may be formed therebetween. The bonding interface IF10 may be free of solder material. In some embodiments, dielectric-to-metal (e.g., oxide-to-copper; not individually shown) bonds may be formed at the bonding interface IF10 of the first semiconductor die 110 and the semiconductor wafer 1200. In some embodiments, the bonding interface IF10 is substantially flat and planar.

In some embodiments, the bonding of the first semiconductor die 110 and the semiconductor wafer 1200 includes a pre-bonding process and an annealing process. During the pre-bonding process, a force may be applied to press the first semiconductor die 110 against the semiconductor wafer 1200. The bonding strength of the first and second bonding dielectric layers (1141 and 1241) may be improved in the annealing process, in which the first and second bonding dielectric layers (1141 and 1241) are annealed at a high temperature. In some embodiments, after the bonding process, the first and second bonding connectors (1142 and 1242) are directly connected to one another with a one-to-one correspondence. In some embodiments, the additional bonding connectors (1142D and 1242D) may be directly connected to one another with a one-to-one correspondence.

It is appreciated that a problem that affects the electrical reliability of the bonded structure is the adhesion between the first semiconductor die 110 and the semiconductor wafer 1200. Poor adhesion may lead to delamination. In some cases, during the bonding process, the first and second bonding connectors may be expanded under the annealed temperature and apply stresses to the surrounding bonding dielectric layers, and hence cause delamination. For example, non-bond areas NB1 exist at a peripheral region of the bonding interface IF10 (e.g., corresponding to the seal ring region 110S). During subsequent processing steps (e.g., the formation of an insulating encapsulant described in FIG. 2C), the large CTE mismatch between the insulating encapsulant and the first/second semiconductor dies may generate stress in the resulting structure, especially at the interface between the insulating encapsulant and the first/second semiconductor dies. Under the thermal mismatch stresses, the non-bond areas NB1 may be enlarged and cracks (if exist) may extend toward the functional region 110A. This may cause the first semiconductor die and the semiconductor wafer to separate and render the resulting structure to be non-functional or failure. Thus, in the manufacture of the semiconductor structure, it is important to prevent the bonding interface from delaminating and prevent any cracks extending into the functional region 110A. As described in greater detail below, to mitigate such delamination, cracking, and/or peeling, some implementations described herein provide a capping layer which seals a perimeter of the bonding interface IF10.

Referring to FIG. 2B and with reference to FIG. 2A, a capping layer 131 may be formed on the first semiconductor die 110 and the semiconductor wafer 1200 to seal the bonding interface IF10. The capping layer 131 may be a single layer or may include a plurality of sublayers formed of different dielectric materials. For example, the material of the capping layer 131 includes any suitable dielectric material such as an oxide (e.g., silicon oxide or the like), a nitride (e.g., silicon nitride or the like), a combination thereof, etc. In some embodiments, the capping layer 131 has a Young's modulus lower than the subsequently-formed insulating encapsulant (“132” labeled in FIG. 2C). The capping layer 131 may be conformally formed on the first semiconductor die 110 and the semiconductor wafer 1200 by chemical vapor deposition (CVD). Other suitable deposition methods (e.g., atomic layer deposition (ALD), physical vapor deposition (PVD), thermal oxidation, a combination thereof, and/or the like) may be used to form the capping layer 131. The capping layer 131 may have a thickness TH1 that is in a range of about 1 μm to about 30 μm. However, any suitable material, process, and thickness may be utilized.

In some embodiments, the capping layer 131 surrounds the bonding interface IF10 and partially covers the first semiconductor die 110 and the semiconductor wafer 1200. For example, the capping layer 131 includes a first portion 1311 and a second portion 1312 connected to the first portion 1311, where the first portion 1311 extends in a first direction D1 and the second portion 1312 extends in a second direction D2. The first direction D1 may be substantially perpendicular to the second direction D2. For example, the first direction D1 is a stacking direction of the first semiconductor die 110 and the semiconductor wafer 1200. The first portion 1311 partially lining the sidewall of the first semiconductor die 110 may be viewed as a vertical portion of the capping layer 131, while the second portion 1312 partially overlying the top surface 1241t of the second bonding dielectric layer 1241 may be viewed as a horizontal portion of the capping layer 131. In some embodiments, the first portion 1311 extends along and physically connected to the sidewall 1141W of the first bonding dielectric layer 1141 and the sidewall 1131W of the first dielectric layer 1131. In some embodiments, the first portion 1311 does not extend upward to cover the sidewall 111W of the first semiconductor substrate 111. In alternative embodiments, the first portion 1311 extends upward to partially (or fully) cover the sidewall 111W of the first semiconductor substrate 111. In some embodiments, the second portion 1312 extends from the sidewall of the first semiconductor die 110 and has a lateral dimension L1 measured in the second direction D2. For example, the lateral dimension L1 is greater than (or substantially equal to) 10 μm. Other lateral dimensions L1 are also possible.

The capping layer 131 lining the sidewalls (1131W and 1141W) of the first semiconductor die 110 and overlying the top surface 1241t of the semiconductor wafer 1200 may function as a dielectric seal which seals the bonding interface IF10. During the formation of the insulating encapsulant (see FIG. 2C), the capping layer 131 may prevent the stress from being directly applied to the perimeter of the bonding interface IF10, thereby enhancing the reliability of the bonded structure. Even if the non-bond areas (e.g., NB1 labeled in FIG. 2A) and/or cracks exist in the bonded structure, the capping layer 131 sealing the bonding interface IF10 may help to prevent delamination/cracks from occurring, becoming more severe, and/or extending into the functional region 110A.

Referring to FIG. 2C and with reference to FIG. 2B, an insulating encapsulant 132 may be formed on the semiconductor wafer 1200 to cover the first semiconductor die 110 and the capping layer 131. In some embodiments, the insulating encapsulant 132 is formed of a molding material or compound and may be formed by compression molding, transfer molding, or the like. The molding material includes a polymer material and optionally includes fillers (not individually illustrated), where the fillers may be particles of silica or the like, and the polymer material may be an epoxy or the like. The fillers mixed in the polymer material may provide mechanical strength and thermal dispersion for the insulating encapsulant 132. For example, the insulating material is formed over the top surface 1241t of the second bonding dielectric layer 1241 of the semiconductor wafer 1200, and the first semiconductor die 110 and the capping layer 131 may be buried or covered by the insulating material. The insulating material may then be cured to form the insulating encapsulant 132. A planarization process (e.g., CMP, grinding, etching, combinations thereof, or the like) is optionally performed on the insulating material to planarize the top surface 132t of the insulating material and the first semiconductor die 110. The planarization process may (or may not) remove back side 111b of the first semiconductor substrate 111. In some embodiments, the back side 111b of the first semiconductor die 110 is exposed by the planarization of the insulating encapsulant 132 such that surfaces (e.g., 111b and 132t) of the first semiconductor die 110 and the insulating encapsulant 132 are substantially level (or coplanar), within process variations.

In some embodiments, the insulating encapsulant 132 extends along the outer surfaces of the first semiconductor die 110 which are not covered by the capping layer 131. For example, the sidewall 111X of the ledge portion 111G, the lower surface 111L of the first semiconductor substrate 111, and the sidewall 111W of the first semiconductor substrate 111 are in physical and direct contact with the insulating encapsulant 132. The capping layer 131 may laterally separate the insulating encapsulant 132 from the first interconnect structure 113 and the first bonding structure 114. The top surface 1241t of the second bonding dielectric layer 1241 of the semiconductor wafer 1200 may include a first portion bonded to the first semiconductor die 110, a second portion surrounding the first portion and covered by the second portion 1312 of the capping layer 131, and a third portion surrounding the second portion and covered by the insulating encapsulant 132. The capping layer 131 may vertically separate the insulating encapsulant 132 from the second portion of the top surface 1241t. As mentioned in the preceding paragraphs, the capping layer 131 may seal between the first semiconductor die 110 and the semiconductor wafer 1200. In this manner, during the formation of the insulating encapsulant 132, the thermal mismatch stress will not directly affect the bonding interface IF10. The presence of the capping layer 131 may help to prevent delamination from occurring (or becoming more severe) and prevent cracks (if exist) from extending into the functional region 110A, thereby improving the reliability of the resulting semiconductor structure.

Still referring to FIG. 2C, a thinning process (e.g., grinding, CMP, etching, combinations thereof, or the like) may be performed on the back side of the semiconductor wafer 1200. For example, the back side 121b of the second semiconductor substrate 121 is thinned down until at least a portion of the second ends 125b of the through vias 125 is accessibly exposed. In some embodiments, the thinning process is performed after the formation of the insulating encapsulant 132. Since the through vias 125 penetrating through the second semiconductor substrate 121, the through vias 125 may be viewed as through-substrate vias (TSVs) 125.

Referring to FIG. 2D and with reference to FIG. 2C, a plurality of conductive terminals 142 may be formed over the back side 121b of the second semiconductor substrate 121 and electrically connected to the TSVs 125. The conductive terminals 142 may be controlled collapse chip connection (C4) bumps, ball grid array (BGA) connectors, solder balls, metal pillars, micro-bumps, electroless nickel-electroless palladium-immersion gold (ENEPIG) formed bumps, or the like. The conductive terminals 142 may include a conductive material such as solder, copper, aluminum, gold, nickel, silver, palladium, tin, the like, or a combination thereof. In some embodiments, the conductive terminals 142 are formed by forming a solder material; and performing a reflow process on the solder material to form desired bump shapes. In some embodiment, the respective conductive terminal 142 includes a pillar portion (e.g., a copper pillar) and a cap portion formed on the pillar portion, where the pillar portion has a substantially vertical sidewall and the cap portion has a bump profile.

In some embodiments, before forming the conductive terminals 142, conductive pads 141 are formed over the second ends 125b of the TSVs 125 and the back side 121b of the second semiconductor substrate 121. The conductive terminals 142 may land on the conductive pads 141 and may be electrically connected to the TSVs 125 through the conductive pads 141. In some embodiments, the conductive pads 141 are under bump metallization (UBM) pads. In alternative embodiments, before forming the conductive terminals 142, a redistribution structure (e.g., 150 labeled in FIG. 4B) is formed over the back side 121b of the second semiconductor substrate 121, and then the conductive terminals 142 are formed on the redistribution structure such that the conductive terminals 142 are electrically connected to the TSVs 125 through the redistribution structure.

Still referring to FIG. 2D and with reference to FIG. 2C, a singulation process is optionally performed by cutting along scribe lanes (not shown) to form individual semiconductor structure 10. For example, the semiconductor structure 10 includes a first tier 101 stacked upon a second tier 102, where the first tier 101 includes the first semiconductor die 110, the capping layer 131, and the insulating encapsulant 132, and the second tier 102 includes the second semiconductor die 120 formed by singulating the semiconductor wafer 1200. After the singulation process, the sidewall 132W of the insulating encapsulant 132 may be substantially aligned (or leveled) with the sidewall 120W of the second semiconductor die 120.

Referring to FIG. 2E and with reference to FIG. 2D, the top view of FIG. 2E illustrates the boundary relationship among the insulating encapsulant 132, the capping layer 131, the first semiconductor die 110, and the second semiconductor die 120. Since the capping layer 131 is buried in the insulating encapsulant 132, the capping layer 131 in FIG. 2E is illustrated by dashed lines. In some embodiments, the boundary of the second semiconductor die 120 is substantially aligned with the outer boundary of the insulating encapsulant 132, where the sidewall 132W of the insulating encapsulant 132 is substantially aligned with the sidewall 120W of the second semiconductor die 120. In some embodiments, the outer boundary 131Y of the capping layer 131 is located within the outer boundary of the insulating encapsulant 132 which is defined by the sidewall 132W. In the top view, the capping layer 131 may be a closed loop (or a continuous ring) encircling the boundaries of the first semiconductor die 110, where the boundaries of the first semiconductor die 110 includes a first boundary defined by the sidewall 111X and a second boundary defined by the sidewall 111W (or 1131W, 1141W). In some embodiments, the inner boundary 131Z of the capping layer 131 is adjoined to the second boundary of the first semiconductor die 110 that is defined by the sidewalls (1131W and 1141W).

The capping layer 131 may have the lateral dimension L1. Depending on the relationship between the lateral dimensions of the capping layer 131 and the ledge portion 111G of the first semiconductor die 110, the first boundary of the first semiconductor die 110 defined by the sidewall 111X may be disposed between the inner boundary 131Z and the outer boundary 131Y of the capping layer 131, as shown in FIG. 2E. In alternative embodiments, the outer boundary 131Y of the capping layer 131 is substantially aligned with the first boundary of the first semiconductor die 110 defined by the sidewall 111X. In other embodiments, outer boundary 131Y of the capping layer 131 is between the first boundary of the first semiconductor die 110 defined by the sidewall 111X and the second boundary of the first semiconductor die 110 that is defined by the sidewalls (1131W and 1141W).

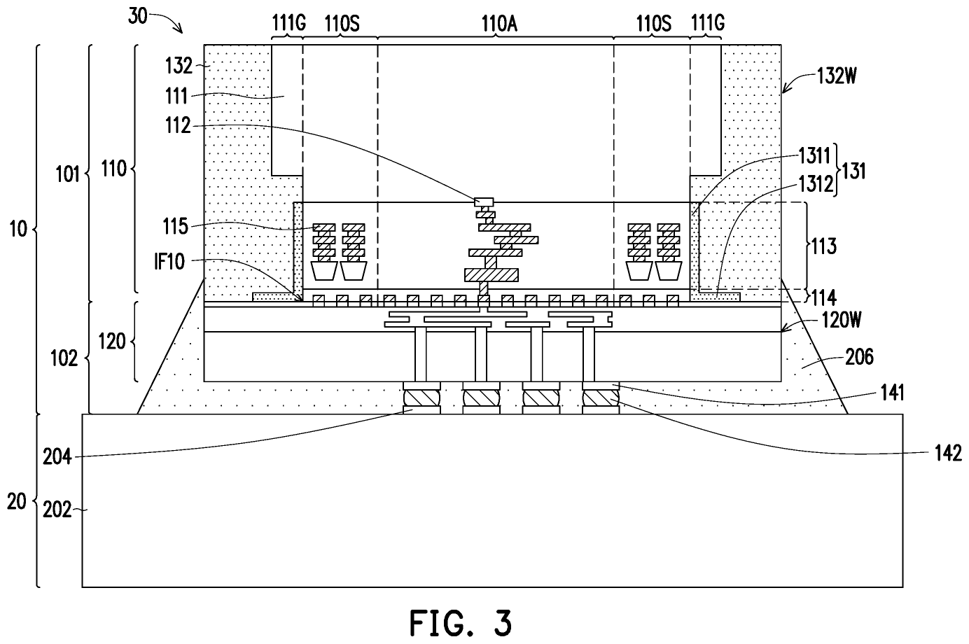

FIG. 3 illustrates schematic a cross-sectional view of an integrated circuit (IC) package including the semiconductor structure 10, in accordance with some embodiments. Like reference numerals denote like features with similar structures and compositions.

Referring to FIG. 3 and with reference to FIG. 2D, the semiconductor structure 10 may be mounted on a package substrate 20 using the conductive terminals 142 to form an IC package 30. The package substrate 20 may include a substrate 202, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. The substrate 202 may be a SOI substrate. Alternatively, the substrate 202 includes an insulating core (not individually illustrated) such as a fiberglass reinforced resin core (e.g., FR4), BT resin core or includes printed circuit board (PCB) materials or films. Build up films (e.g., Ajinomoto build-up film or other laminates; not individually illustrated) may be used for the substrate 202. The substrate 202 may include active and/or passive devices (not illustrated) to generate the functional requirements of the design for the system.

The package substrate 20 may include contact pads 204 formed on/in the substrate 202. The conductive terminals 142 may be reflowed to attach the conductive pads 141 to the contact pads 204. After coupling the conductive terminals 142 to the contact pads 204, the semiconductor structure 10 may be electrically coupled to the package substrate 20. In some embodiments, the IC package 30 includes an underfill 206 formed between the semiconductor structure 10 and the package substrate 20, where the underfill 206 may surround the conductive terminals 142 and the conductive pads 141 for protection. The underfill 206 may be formed by a capillary flow process after the semiconductor structure 10 is attached or may be formed by a suitable deposition method before the semiconductor structure 10 is attached. The underfill 206 may be a continuous material extending from the package substrate 20. In some embodiments, the underfill 206 extends upward to be in physical contact with the sidewall 120W of the second semiconductor die 120. The underfill 206 may further physically contact the sidewall 132W of the insulating encapsulant 132 according to some embodiments. The outer surfaces of the underfill 206 may be slanted or curved due to the surface tension and the capillary flow process. Unlike the underfill 206, the outer surfaces of the capping layer 131 may be substantially straight or substantially parallel to the sidewalls/surfaces of the first/second semiconductor dies 110/120. The above examples are provided for illustrative purposes only, and the IC package 30 may include fewer or additional elements, in other embodiments.

FIG. 4A and FIG. 4B illustrate schematic cross-sectional views of intermediate steps during a process for forming a semiconductor structure, in accordance with some embodiments. Unless specified otherwise, the materials and the formation methods of the components in these embodiments are essentially the same as the like components, which are denoted by like reference numerals in the embodiments shown in FIGS. 2A through 2D. The details regarding the formation process and the materials of the components shown in FIGS. 4A-4B may be found in the discussion of the previous embodiments.

Referring to FIG. 4A and with reference to FIG. 2B, the structure shown in FIG. 4A is similar to the structure shown in FIG. 2B, except for the capping layer 231. In the illustrated embodiment, the capping layer 231 is formed on the semiconductor wafer 1200 and the first semiconductor die 110. The capping layer 231 may be substantially conformal to the shape of the semiconductor wafer 1200 and the first semiconductor die 110. The term “substantially conformal” as used herein means that an outer surface of the capping layer 231 is substantially parallel to sidewalls/surfaces of the semiconductor wafer 1200 and the first semiconductor die 110. The capping layer 231 may be a single layer or may include a plurality of sublayers formed of different dielectric materials. The material and the forming method of the capping layer 231 may be similar to those of the capping layer 131 described in FIG. 2B. In some embodiments, the capping layer 231 includes a first portion 2311 lining the second portion 110N of the first semiconductor die 110, a second portion 2312 overlying the second bonding dielectric layer 1241 of the semiconductor wafer 1200, and a third portion 2313′ lining the first portion 110W of the first semiconductor die 110.

In some embodiments, the first portion 2311 of the capping layer 231 extends along the first direction D1 to be in physical contact with the sidewalls (111W, 1131W, and 1141W) of the first semiconductor substrate 111, the first dielectric layer 1131, and the first bonding dielectric layer 1141. The second portion 2312 of the capping layer 231 may extend along the second direction D2 to fully (or partially) cover the portion of the top surface 1241t of the second bonding dielectric layer 1241 which is not bonded to the first semiconductor die 110. The third portion 2313′ of the capping layer 231 may be in physical contact with the lower surface 111L and the sidewall 111X of the first semiconductor substrate 111. The third portion 2313′ may (or may not) cover the back side 111b of the first semiconductor substrate 111.

Referring to FIG. 4B and with reference to FIG. 4A and FIG. 2C, the insulating encapsulant 132 may be formed on the semiconductor wafer 1200 after forming the capping layer 231. The material and the forming method of the insulating encapsulant 132 may be similar to those of the insulating encapsulant 132 described in FIG. 2C. In some embodiments, a planarization process (e.g., CMP, grinding, etching, combinations thereof, or the like) is performed. During the planarization process, a part of the third portion 2313′ overlying the first semiconductor die 110 may be removed to reveal the back side 111b of first semiconductor substrate 111. For example, the surfaces (e.g., 111b and 132t) of the first semiconductor die 110 and the insulating encapsulant 132 are substantially level (or coplanar), within process variations, after the planarization process. In some embodiments, the top surface 131t of the capping layer 131 is planarized during the planarization process and substantially leveled (or coplanar) with the surfaces (e.g., 111b and 132t) of the first semiconductor die 110 and the insulating encapsulant 132, within process variations.

With continued reference to FIG. 4B, FIG. 4A, and FIGS. 2C-2D, a thinning process may be performed on the back side 121b of the second semiconductor substrate 121 until at least a portion of the TSVs 125 is accessibly exposed. The thinning process may be similar to the process described in FIG. 2C. In some embodiments, a redistribution structure 150 is formed on the back side 121b of the second semiconductor substrate 121. For example, the redistribution structure 150 includes one or more dielectric layer(s) 151 and conductive patterns 152 formed in the dielectric layer 151 and electrically connected to the TSVs 125. The dielectric layer 151 may be formed of any suitable dielectric material such as polybenzoxazole (PBO), polyimide, a benzocyclobuten (BCB), a combination thereof, or the like. The conductive patterns 152 may include conductive pads, conductive vias, conductive lines, a combination thereof, or the like, and may be formed of any suitable conductive material such as copper, cobalt, aluminum, gold, combinations thereof, or the like. In some embodiments, the conductive patterns 152 include UBM pads, and the conductive terminals 142 may be formed on the UBM pads. In alternative embodiments, the redistribution structure 150 is replaced with the conductive pads 141 described in FIG. 2D.

Still referring to FIG. 4B and with reference to FIG. 2D and FIG. 3, a singulation process is optionally performed by cutting along scribe lanes (not shown) to form individual semiconductor structure 10A. The semiconductor structure 10A is optionally mounted on the package substrate 20 using the conductive terminals 142 to form an IC package as described in FIG. 3. For example, the semiconductor structure 10A includes a first tier 101′ stacked upon a second tier 102′, where the first tier 101′ includes the first semiconductor die 110, the capping layer 231, and the insulating encapsulant 132, while the second tier 102′ includes the second semiconductor die 120 formed by singulating the semiconductor wafer 1200. The singulation process may be similar to the process described in FIG. 2D, and thus the detail descriptions are not repeated herein. After the singulation process, the sidewall 2312W of the second portion 2312 of the capping layer 231 is substantially aligned (or coplanar) with the sidewall 132W of the insulating encapsulant 132 and the sidewall 120W of the second semiconductor die 120.

In the illustrated embodiments, the first tier 101′ of the semiconductor structure 10A includes the capping layer 231 spatially separating the insulating encapsulant 132 from the first semiconductor die 110 and also vertically separating the insulating encapsulant 132 from the second semiconductor die 120. The capping layer 231 may function as a dielectric seal isolating the insulating encapsulant 132 from the first and second semiconductor dies (110 and 120). The presence of the capping layer 231 may help to reduce the risk of delamination propagation during the formation of the insulating encapsulant 132. Accordingly, the semiconductor structure 10A with reduced defects, improved reliability, and improved yield can be achieved.

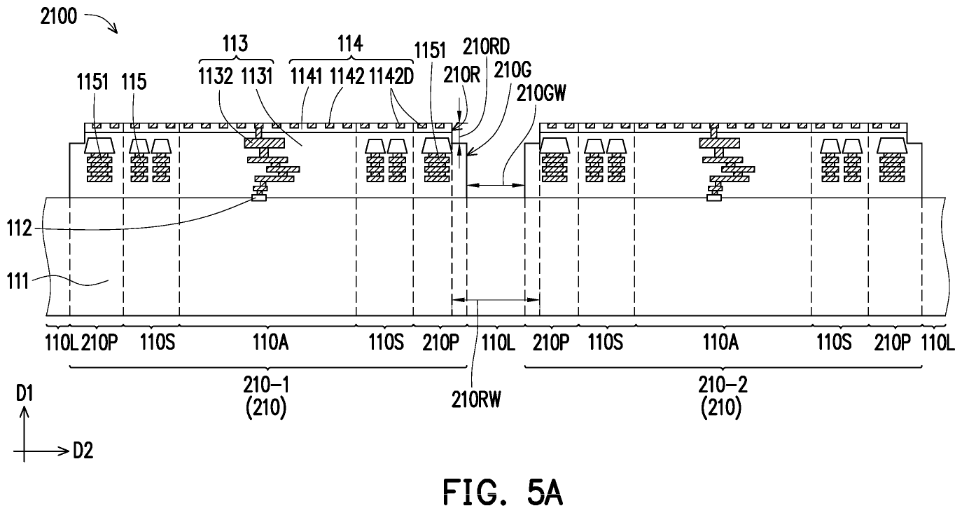

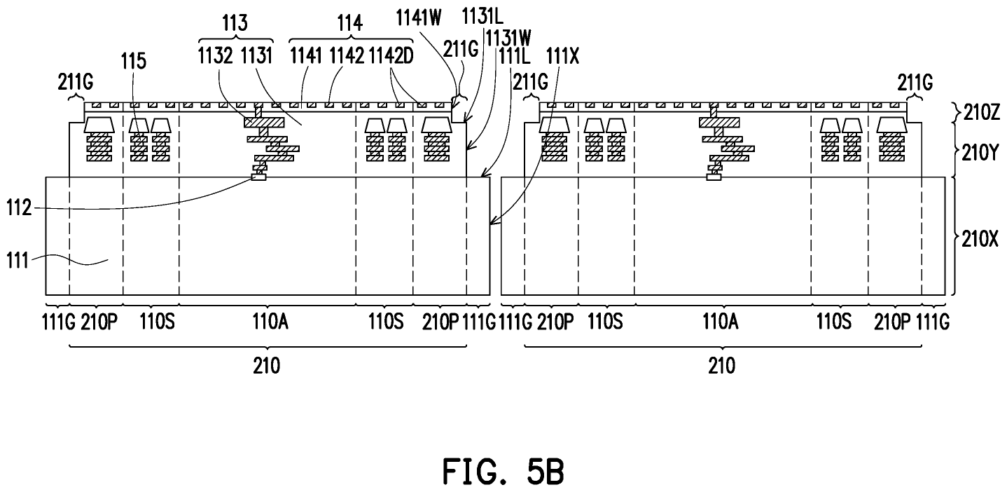

FIG. 5A and FIG. 5B illustrate schematic cross-sectional views of intermediate steps during a process for forming a first semiconductor die, in accordance with some embodiments. Unless specified otherwise, the materials and the formation methods of the components in these embodiments are essentially the same as the like components, which are denoted by like reference numerals in the embodiments shown in FIGS. 1A through 1C. The details regarding the formation process and the materials of the components shown in FIGS. 5A-5B may be found in the discussion of the previous embodiments.

Referring to FIG. 5A and with reference to FIGS. 1A-1B, a semiconductor wafer 2100 is provided. The semiconductor wafer 2100 may be similar to the semiconductor wafer 1100, except that the semiconductor wafer 2100 further includes a peripheral region 210P between the seal ring region 110S and the scribe line region 110L. In some embodiments, additional seal rings 1151 are disposed in the peripheral region 210P and embedded in the first dielectric layer 1131. In some embodiments, additional bonding connectors 1142D embedded in the first bonding dielectric layer 1141 are distributed over the seal rings 115 and the additional seal rings 1151. The additional bonding connectors 1142D may (or may not) be physically connected to the underlying seal rings 115 and/or the additional seal rings 1151.

In some embodiments, recesses 210R are formed in the semiconductor wafer 2100 by etching, plasma dicing, or any suitable removal process. For example, forming the recesses 210R includes forming a patterned mask (not shown) on the semiconductor wafer 2100, and then etching portions of the semiconductor wafer 2100 exposed by the patterns (e.g., openings) in the patterned mask. For example, the recesses 210R are formed in the scribe line regions 110L and may further extend into the peripheral regions 210P adjoined to the scribe line regions 110L. For example, a portion of the first bonding structure 114 in the peripheral regions 210P is removed after the recesses 210R are formed. In some embodiments, a portion of the first dielectric layer 1131 underlying the portion of the first bonding structure 114 in the peripheral regions 210P is also removed, depending on the depth 210RD of the respective recess 210R. The depth 210RD measured in the first direction D1 may be in a range of about 5kÅ to about 5 μm. The lateral dimension (e.g., width) 210RW of the respective recess 210R may vary depending on process requirements and construe no limitation in the disclosure. The recesses 210R may be referred to as shallow recesses.

With continued reference to FIG. 5A, a grooving process (e.g., laser grooving, plasma dicing, or the like) may be performed on the semiconductor wafer 2100 after the formation of the recesses 210R. For example, grooves 210G are formed within the scribe line regions 110L between adjacent die regions (210-1 and 210-2) by the grooving process. The grooving process may be performed through the respective recess 210R such that the respective groove 210G is connected to the corresponding recess 210R. The respective groove 210G may extend along the first direction D1 from the corresponding recess 210R to the first dielectric layer 1311. For example, the respective groove 210G penetrates through the first dielectric layer 1311. In some embodiments, the grooves 210G extend vertically into the first semiconductor substrate 111. In some embodiments, the respective groove 210G has a lateral dimension (e.g., the width) 210GW less than the lateral dimension 210RW of the respective recess 210R.

Referring to FIG. 5B and with reference to FIG. 5A and FIG. 1C, a sawing process may be performed on the semiconductor wafer 2100 to fully separate the die regions (210-1 and 210-2) from each other to form individual first semiconductor dies 210. The sawing process may be performed through the respective recess 210R and the underlying groove 210G in the scribe line regions 110L. In some embodiments, the sawing process is a mechanical process using a saw blade that is placed in the respective recess 210R and the underlying groove 210G to saw through the remaining first semiconductor substrate 111. Other sawing processes may be used in other embodiments.

After the sawing process, each singulated, first semiconductor die 210 may include a first ledge portion 111G formed by the first semiconductor substrate 111 and a second ledge portion 211G formed by the first interconnect structure 131. In the cross-sectional view, the sidewall of the first semiconductor die 210 may have a stepped profile. For example, the sidewall 111X of the first ledge portion 111G is formed through the sawing process and the lower surface 111L of the first ledge portion 111G is formed through the grooving process. The sidewall 1131W of the second ledge portion 211G may be formed through the grooving process, and the lower surface 1131L of the second ledge portion 211G connected to the sidewall 1131W may be formed through the etching process. The sidewall 1141W of the first bonding layer 1141 may be formed through the etching process. Due to differences in the etching/grooving/sawing processes, surfaces of different regions of the first semiconductor die 210 may have different roughness. For example, surfaces (e.g., 1141W, 1131L, 1131W, and 111L), which are formed by etching/grooving, may be smoother than the sidewall 111X of the first semiconductor substrate 111, which is formed by sawing.

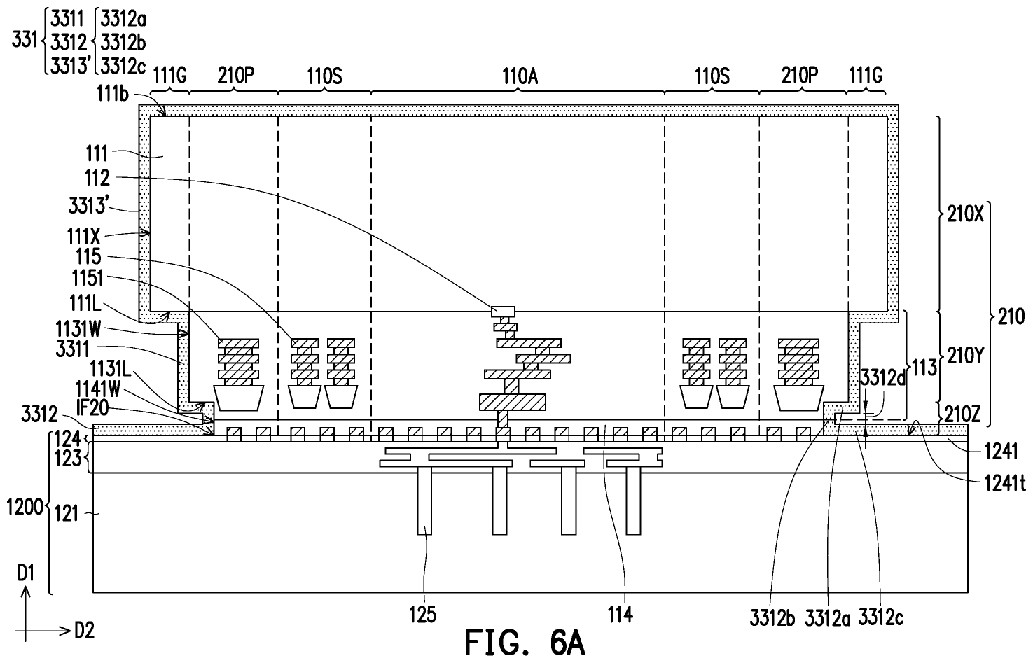

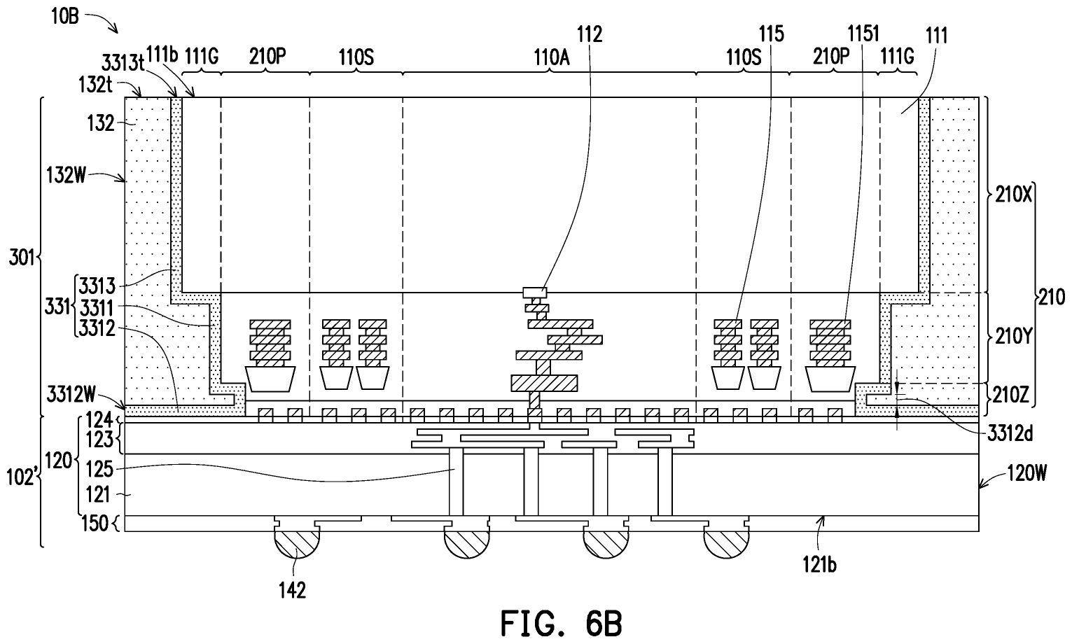

As shown in FIG. 5B, the respective first semiconductor die 210 may include a first portion 210X, a second portion 210Y connected to the first portion 210X, and a third portion 210Z connected to the second portion 210Y, where the first portion 210X is the first semiconductor substrate 111, the second portion 210Y is the first interconnect structure 131 or include a part of the first interconnect structure 131, and the third portion 210Z is the first bonding structure 141 or include the first bonding structure 141 and a portion of the first interconnect structure 131 underlying the first bonding structure 141. The first portion 210X may be laterally protruded from the second portion 210Y, and the second portion 210Y may be laterally protruded from the third portion 210Z. The first portion 210X may be wider than the second portion 210Y, and the second portion 210Y may be wider than the third portion 210Z. For example, the difference between the lateral dimensions of the first and second portions (210X and 210Y) is the lateral dimension of the first ledge portion 111G, and the difference between the lateral dimensions of the second and third portions (210Y and 210Z) is the lateral dimension of the second ledge portion 211G. In some embodiments, the presence of the first and second ledge portions (111G and 211G) helps to avoid stress concentration on the periphery of the bonding interface during the formation of the insulating encapsulant (see FIGS. 6A-6B).

FIG. 6A and FIG. 6B illustrate schematic cross-sectional views of intermediate steps during a process for forming a semiconductor structure, in accordance with some embodiments. Unless specified otherwise, the materials and the formation methods of the components in these embodiments are essentially the same as the like components, which are denoted by like reference numerals in the embodiments shown in FIGS. 2A-2D and FIGS. 4A-4B. The details regarding the formation process and the materials of the components shown in FIGS. 6A-6B may be found in the discussion of the previous embodiments.

Referring to FIG. 6A and with reference to FIG. 5B and FIGS. 2A-2B or FIG. 4A, the first semiconductor die 210 may be bonded to the semiconductor wafer 1200. The bonding process of the first semiconductor die 210 and the semiconductor wafer 1200 may be similar to the process described in FIG. 2A. For example, the first bonding structure 114 of the first semiconductor die 210 may be bonded to the second bonding structure 214 of the semiconductor wafer 1200, and the bonding interface IF20 of the first semiconductor die 210 and the semiconductor wafer 1200 may be substantially flat and planar. In some embodiments, a capping layer 331 is conformally (or blanketly) formed on the semiconductor wafer 1200 and the first semiconductor die 210. The capping layer 331 may be a single layer or may include a plurality of sublayers formed of different dielectric materials. The material and the forming method of the capping layer 331 may be similar to those of the capping layer 131 described in FIG. 2B or the capping layer 231 described in FIG. 4A.

In some embodiments, the capping layer 331 includes a first portion 3311 lining the second portion 210Y of the first semiconductor die 210, a second portion 3312 lining the third portion 210Z of the first semiconductor die 210 and overlying the semiconductor wafer 1200, and a third portion 3313′ lining the first portion 210X of the first semiconductor die 210. The first portion 3311 may extend along the first direction D1 to be in physical contact with the sidewall 1131W of the first dielectric layer 1131. The second portion 3312 may include a first part 3312a connected to the first portion 3311 and covering the lower surface 1131L of the dielectric layer 1131, a second part 3312b connected to the first part 3312a and lining the sidewall 1141W of the first bonding dielectric layer 1141, and a third part 3312c connected to the second part 3312b and overlying the top surface 1241t of the second bonding dielectric layer 1241, where the first part 3312a and the third part 3312c extend along the second direction D2 and the second part 3312b extends along the first direction D1. In some embodiments, a gap is formed between the first part 3312a and the third part 3312c by a vertical distance 3312d, where the vertical distance 3312d is non-zero. For example, the vertical distance 3312d is in a range of about 1kÅ to about 4 μm. The third portion 3313′ may be in physical contact with the lower surface 111L and the sidewall 111X of the first semiconductor substrate 111. The third portion 3313′ may (or may not) cover the back side 111b of the first semiconductor substrate 111. In alternative embodiments, the entirety of the third portion 3313′ is omitted and/or the third part of the second portion 3312 may partially cover the top surface 1241t of the second bonding dielectric layer 1241 as described in FIG. 2B.

Referring to FIG. 6B and with reference to FIG. 6A and FIGS. 2C-2D or FIG. 4B, the insulating encapsulant 132 may be formed on the semiconductor wafer 1200 to cover the capping layer 331 and the first semiconductor die 210. The material and the forming method of the insulating encapsulant 132 may be similar to those of the insulating encapsulant 132 described in FIG. 2C. In some embodiments, the vertical distance 3312d is large enough such that the insulating encapsulant 132 may extend to fill the gap. In some embodiments, a planarization process (e.g., CMP, grinding, etching, combinations thereof, or the like) is performed. During the planarization process, a part of the third portion 3313′ overlying the first semiconductor die 210 may be removed to reveal the first semiconductor substrate 111. For example, the surfaces (e.g., 111b, 132t, 3313t) of the first semiconductor die 210, the insulating encapsulant 132, and the third portion 3313 are substantially level (or coplanar), within process variations, after the planarization process.

In some embodiments, a thinning process is performed on the back side 121b of the second semiconductor substrate 121 until at least a portion of the TSVs 125 is accessibly exposed. The thinning process may be similar to the process described in FIG. 2C. In some embodiments, the redistribution structure 150 is formed on the back side 121b of the second semiconductor substrate 121. The redistribution structure 150 may be similar to the redistribution structure 150 described in FIG. 4B. In some embodiments, the conductive terminals 142 are formed on the pads of the redistribution structure 150 to be electrically coupled to the TSVs 125 through the redistribution structure 150. In alternative embodiments, the redistribution structure 150 is replaced with the conductive pads 141 described in FIG. 2D.

Still referring to FIG. 6B and with reference to FIG. 2D, FIG. 3, or FIG. 4B, a singulation process is optionally performed by cutting along scribe lanes (not shown) to form individual semiconductor structure 10B. The semiconductor structure 10B is optionally mounted on the package substrate 20 using the conductive terminals 142 to form an IC package as described in FIG. 3. For example, the semiconductor structure 10B includes a first tier 301 stacked upon the second tier 102′, where the first tier 301 includes the first semiconductor die 210, the capping layer 331, and the insulating encapsulant 132, and the second tier 102′ includes the second semiconductor die 120 formed by singulating the semiconductor wafer 1200. The singulation process may be similar to the process described in FIG. 2D. For example, after the singulation process, the sidewalls (e.g., 132W, 3312W, and 120W) of the insulating encapsulant 132, the second portion 3312 of the capping layer 331, and the second semiconductor die 120 are substantially leveled (or coplanar) with one another, within process variations. In the illustrated embodiments, the first tier 301 includes the capping layer 331 spatially separating the insulating encapsulant 132 from the first semiconductor die 210 and also separating the insulating encapsulant 132 from the second semiconductor die 120. The capping layer 331 may function as a dielectric seal isolating the insulating encapsulant 132 from the first and second semiconductor dies (210 and 120). In alternative embodiments, the third portion 3313 of the capping layer 331 is omitted and/or the first portion 3312 may partially cover the second semiconductor die 120 as described in FIG. 2B. The presence of the capping layer 331 may help to reduce the risk of delamination propagation during the formation of the insulating encapsulant 132. Accordingly, the semiconductor structure 10B with reduced defects, improved reliability, and improved yield can be achieved.

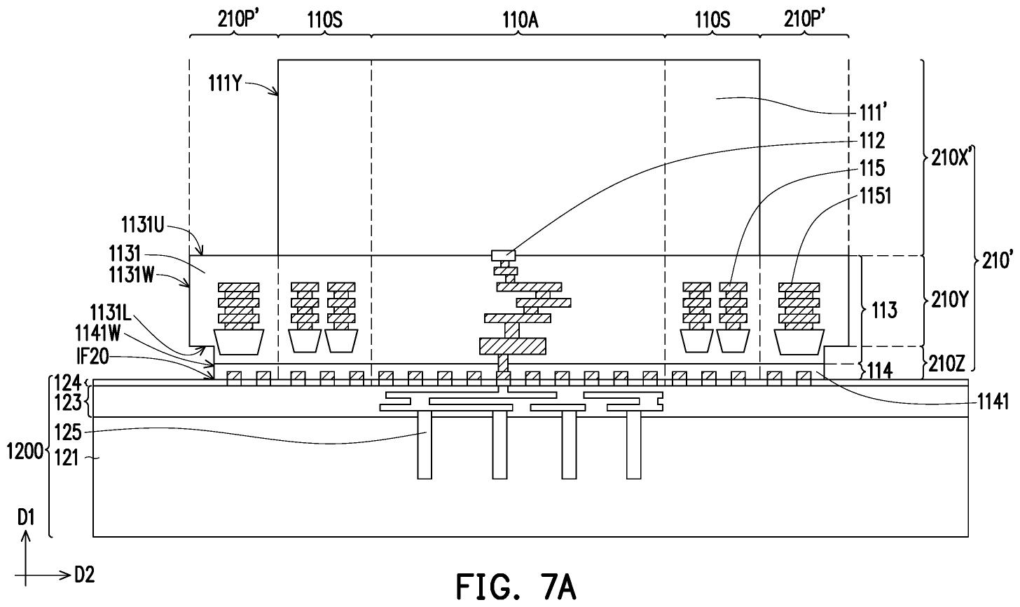

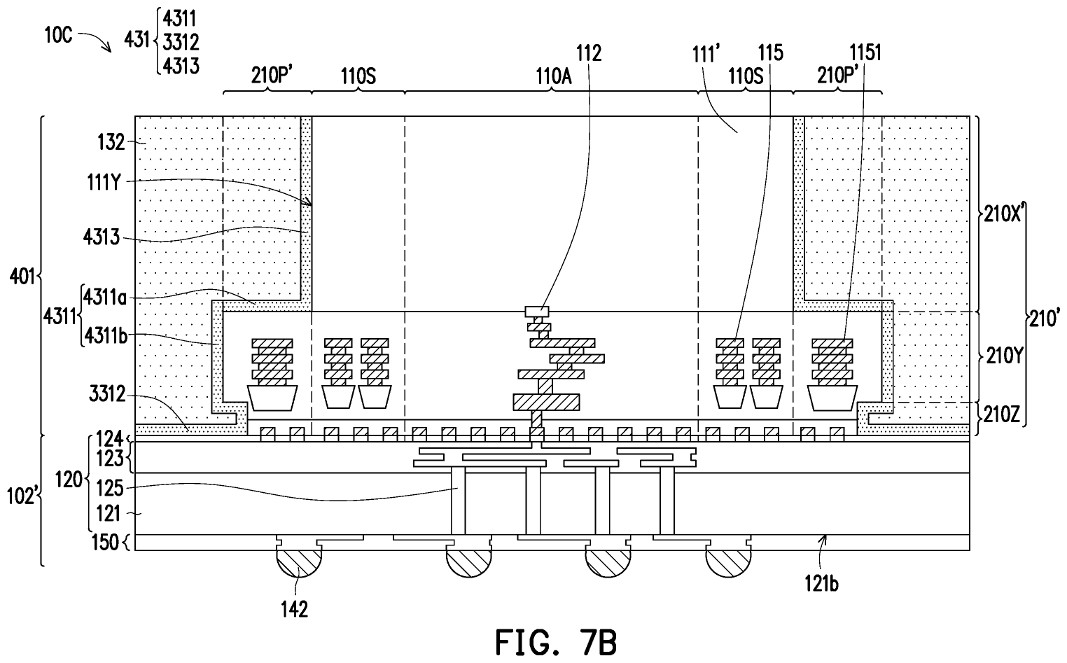

FIG. 7A and FIG. 7B illustrate schematic cross-sectional views of intermediate steps during a process for forming a semiconductor structure, in accordance with some embodiments. Unless specified otherwise, the materials and the formation methods of the components in these embodiments are essentially the same as the like components, which are denoted by like reference numerals in the embodiments shown in FIGS. 6A-6B. The details regarding the formation process and the materials of the components shown in FIGS. 7A-7B may be found in the discussion of the previous embodiments.

Referring to FIG. 7A and with reference to FIG. 5B and FIG. 6A, the first semiconductor 210 may be bonded to the semiconductor wafer 1200. The bonding process of the first semiconductor die 210 and the semiconductor wafer 1200 may be similar to the process described in FIG. 2A or FIG. 6A. For example, the first bonding structure 114 of the first semiconductor die 210 may be bonded to the second bonding structure 214 of the semiconductor wafer 1200, and the bonding interface IF20 of the first semiconductor die 210 and the semiconductor wafer 1200 may be substantially flat and planar. After the bonding process, a portion of the first semiconductor substrate 111 may be removed through etching, dicing, sawing, combinations thereof, or any suitable removal process. In some embodiments, a portion of the first semiconductor substrate 111 in the peripheral region 210P is removed. In some embodiments, not only a portion of the first semiconductor substrate 111 in the peripheral region 210P but a portion of the first semiconductor substrate 111 in the seal ring region 110S may be removed.

In some embodiments, after the partially removing of the first semiconductor substrate 111, the first semiconductor die 210′ includes a first semiconductor substrate 111′ having a sidewall 111Y. The sidewall 111Y of the first semiconductor substrate 111′, the sidewall 1131W of the first dielectric layer 1131, and the sidewall 1141W of the first bonding dielectric layer 1141 may be laterally offset from one another. The first semiconductor die 210′ may include a first portion 210X′ having a lateral dimension (e.g., width) less than the second portion 210Y, and the third portion 210Z having the lateral dimension (e.g., width) greater than the first portion 210X′ and less than the second portion 210Y. For example, the lateral dimension (e.g., width) of the first semiconductor substrate 111′ measured in the second direction D2 is less than that of the first interconnect structure 113 and the first bonding structure 114. In some embodiments, an upper surface 1131U of the first dielectric layer 1131 connected to the sidewall 1131W and opposite to the lower surface 1131L is accessibly exposed after forming the first semiconductor substrate 111′. The additional seal ring 1151 within the peripheral region 210P′ may be underneath the upper surface 1131U of the first dielectric layer 1131.

Referring to FIG. 7B and with reference to FIG. 7A and FIGS. 6A-6B, a capping layer 431 may be conformally (or blanketly) formed on the semiconductor wafer 1200 and the first semiconductor die 210′. The capping layer 431 may be similar to the capping layer 331 described in FIGS. 6A-6B, except for the first portion 4311 and the third portion 4313. For example, the first portion 4311 of the capping layer 431 includes a first part 4311a extending along the second direction D2 to cover the upper surface 1131U and a second part 4311b extending along the first direction D1 to cover the sidewall 1311W. The sidewall 111Y of the first semiconductor substrate 111′ may be lined with the third portion 4313 of the capping layer 431. In alternative embodiments, the third portion 4313 is omitted and/or the second portion 3312 may partially cover the second bonding structure 124 as described in FIG. 2B.

After forming the capping layer 431, the insulating encapsulant 132 may be formed on the semiconductor wafer 1200 to cover the capping layer 431 and the first semiconductor die 210. In some embodiments, a thinning process is performed on the semiconductor wafer 1200 to accessibly reveal the TSVs 125. The redistribution structure 150 is optionally formed on the back side 121b of the second semiconductor substrate 121 to be electrically connected to the TSVs 125. The conductive terminals 142 may then be formed on the redistribution structure 150. A singulation process is optionally performed by cutting along scribe lanes (not shown) to form individual semiconductor structure 10C. The semiconductor structure 10C is optionally mounted on the package substrate 20 (see FIG. 3) using the conductive terminals 142 to form an IC package. The formation of the insulating encapsulant 132, the thinning process, the formation of the redistribution structure 150, the formation of the conductive terminals 142, and the singulation process may be similar to the formations/processes described in FIG. 6B, and thus the detailed descriptions are not repeated.

With continued reference to FIG. 7B and FIG. 6B, the semiconductor structure 10C including a first tier 401 stacked upon the second tier 102′ may be similar to the semiconductor structure 10B, except for the first portion 210X′ of the first semiconductor die 210′, the capping layer 431 associated with the first portion 210X′, and the insulating encapsulant 132 corresponding to the first portion 210X′. The capping layer 431 may function as a dielectric seal isolating the insulating encapsulant 132 from the first and second semiconductor dies (210′ and 120). The presence of the capping layer 431 may help to reduce the risk of delamination propagation during the formation of the insulating encapsulant 132. Accordingly, the semiconductor structure 10C with reduced defects, improved reliability, and improved yield can be achieved.

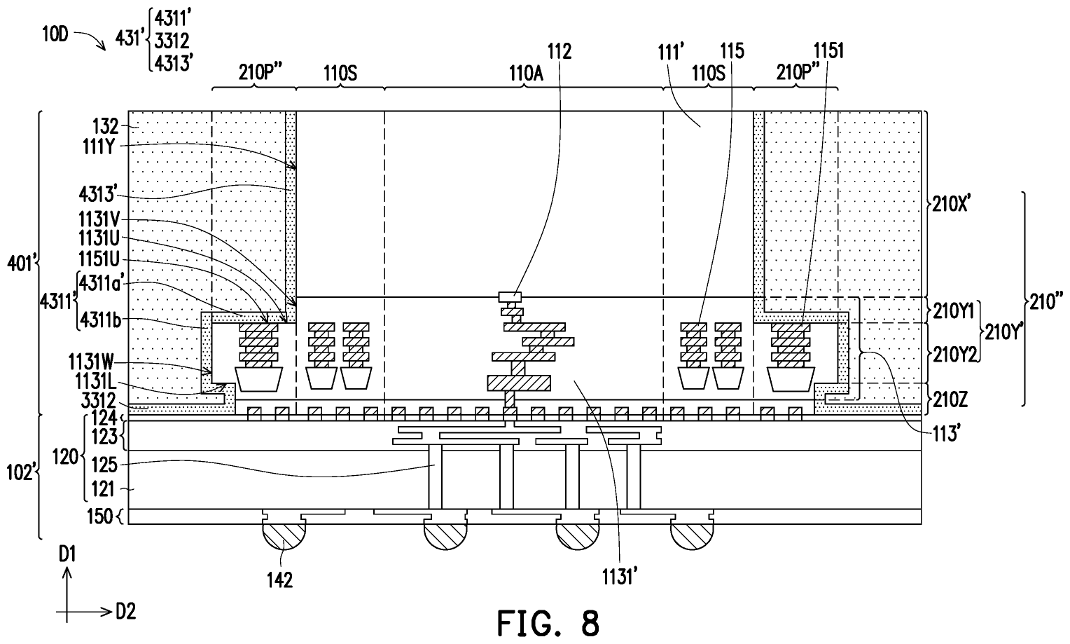

FIG. 8 illustrates a schematic cross-sectional view of a semiconductor structure, in accordance with some embodiments. Unless specified otherwise, the materials and the formation methods of the components in these embodiments are essentially the same as the like components, which are denoted by like reference numerals in the embodiments shown in FIGS. 7A-7B. The details regarding the formation process and the materials of the components shown in FIG. 8 may be found in the discussion of the previous embodiments.

Referring to FIG. 8 and with reference to FIGS. 7A-7B, a semiconductor structure 10D including a first tier 401′ stacked upon the second tier 102′ may be similar to the semiconductor structure 10C of FIG. 7B, except for the second portion 210Y′ of the first semiconductor die 210″, the capping layer 431 associated with the second portion 210Y′, and the insulating encapsulant 132 corresponding to the second portion 210Y′. For example, during the process of removing a portion of the first semiconductor substrate 111 in the peripheral region 210P as described in FIG. 7A, a portion of the first dielectric layer 1131′ underlying the portion of the first semiconductor substrate 111 is also removed. In some embodiments, the portion of the first dielectric layer 1131′ is removed to expose the additional seal ring 1151. For example, the additional seal ring 1151 serves as a stop layer during the removal process. The second portion 210Y′ of the first semiconductor die 210″ may include a first part 210Y1 connected to the first portion 210X and a second part 210Y2 vertically between the first part 210Y1 and the third portion 210Z. The lateral dimension of the first part 210Y1 measured in the second direction D2 may be less than that of the second part 210Y2.

In some embodiments, the first dielectric layer 1131′ of the first semiconductor die 210″ includes a sidewall 1131V substantially aligned with the sidewall 111Y of the first semiconductor substrate 111′, an upper surface 1131U′ connected to the sidewall 1131V, the sidewall 1131W connected to the upper surface 1131U′ and laterally offset from the sidewall 1131V, and the lower surface 1131L connected to the 1131W. The upper surface 1151U of the additional seal ring 1151 may be exposed by the upper surface 1131U′ of the first dielectric layer 1131′. For example, the upper surface 1151U of the additional seal ring 1151 is substantially leveled (or coplanar) with the upper surface 1131U′ of the first dielectric layer 1131′, within process variations. In some embodiments, the upper surface 1151U of the additional seal ring 1151 is protruded from the upper surface 1131U′ of the first dielectric layer 1131′. In alternative embodiments, the additional seal ring 1151 remains (partially or fully) covered by the first dielectric layer 1131′.

With continued reference to FIG. 8, the capping layer 431′ may be conformally (or blanketly) formed on the second semiconductor die 120 and the first semiconductor die 210″. The capping layer 431′ may be similar to the capping layer 431 described in FIG. 7B, except that the first part 4311a′ of the first portion 4311′ covers the upper surfaces (1131U and 1151U) and the third portion 4313′ extends to cover the sidewall 1131V of the first dielectric layer 1131. In some embodiments, the first part 4311a′ is in direct contact with the upper surface 1151U of the additional seal ring 1151. In alternative embodiments, the portion of the 4313′ lining the sidewall 111Y of the first semiconductor substrate 111′ is omitted and/or the second portion 3312 may partially cover the second bonding structure 124 as described in FIG. 2B. The capping layer 431′ may function as a dielectric seal isolating the insulating encapsulant 132 from the first and second semiconductor dies (210″ and 120). The presence of the capping layer 431′ may help to reduce the risk of delamination propagation during the formation of the insulating encapsulant 132. Accordingly, the semiconductor structure 10D with reduced defects, improved reliability, and improved yield can be achieved. The semiconductor structure 10D is optionally mounted on the package substrate 20 (see FIG. 3) using the conductive terminals 142 to form an IC package.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor structure includes a first semiconductor die and a second semiconductor die stacked upon and bonded to one another, a capping layer sealing a bonding interface of the first and second semiconductor dies, and an insulating encapsulant disposed over the second semiconductor die and covering the first semiconductor die and the capping layer. The first semiconductor die includes a first portion and a second portion connected to the first portion, and the first portion is wider than the second portion.

According to some alternative embodiments, a semiconductor structure includes a first semiconductor die including a first sidewall and a second sidewall laterally displaced from the first sidewall, a second semiconductor die underlying and bonded to the first semiconductor die, and an insulating encapsulant covering the first semiconductor die, the second semiconductor die, and the capping layer. The capping layer separates the insulating encapsulant from the first and second semiconductor dies.

According to some alternative embodiments, a manufacturing method of a semiconductor structure includes: bonding a first semiconductor die to a second semiconductor die, where the first semiconductor die includes a first portion and a second portion connected to the first portion, and the first portion is wider than the second portion; forming a capping layer to seal a bonding interface of the first and second semiconductor dies; and forming an insulating encapsulant over the second semiconductor die to cover the first semiconductor die and the capping layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first semiconductor die and a second semiconductor die stacked upon and bonded to one another, the first semiconductor die comprising a first portion and a second portion connected to the first portion, and the first portion being wider than the second portion;
a capping layer sealing a bonding interface of the first and second semiconductor dies; and
an insulating encapsulant disposed over the second semiconductor die and covering the first semiconductor die and the capping layer.

2. The semiconductor structure of claim 1, wherein the first semiconductor die comprises:
an interconnect structure underlying a semiconductor substrate;
a bonding structure underlying the interconnect structure and electrically coupled to the interconnect structure and the second semiconductor die, wherein the capping layer conformally extends along the interconnect structure and the bonding structure.

3. The semiconductor structure of claim 2, wherein a sidewall of the interconnect structure is laterally offset from a sidewall of the bonding structure.

4. The semiconductor structure of claim 1, wherein:
the first portion of the first semiconductor die is an upper part of a semiconductor substrate, and
the second portion of the first semiconductor die comprises a lower part of the semiconductor substrate, an interconnect structure underlying the semiconductor substrate, and a bonding structure underlying the interconnect structure, wherein the lower part is connected to the upper part, and the bonding structure is electrically coupled to the interconnect structure and the second semiconductor die.

5. The semiconductor structure of claim 1, wherein:
the first portion of the first semiconductor die is a semiconductor substrate,
the second portion of the first semiconductor die is an interconnect structure underlying the semiconductor substrate, and
the first semiconductor die further comprises a bonding structure underlying and narrower than the second portion, the bonding structure is electrically coupled to the interconnect structure and the second semiconductor die.

6. The semiconductor structure of claim 1, wherein:
the first portion of the first semiconductor die is an interconnect structure,
the second portion of the first semiconductor die is a semiconductor substrate overlying the interconnect structure, and
the first semiconductor die further comprises a bonding structure underlying and wider than the second portion, the bonding structure is electrically coupled to the interconnect structure and the second semiconductor die.

7. The semiconductor structure of claim 1, wherein first semiconductor die comprises a seal ring, and the capping layer is in physical contact with the seal ring.

8. The semiconductor structure of claim 1, wherein a topmost surface of the second semiconductor die comprises a first portion bonded to the first semiconductor die, a second portion surrounding the first portion and physically connected to the capping layer, and a third portion surrounding the second portion and physically connected to the insulating encapsulant.

9. The semiconductor structure of claim 1, wherein the bonding interface is free of solder material.

10. The semiconductor structure of claim 1, wherein back sides of the first semiconductor die and the insulating encapsulant are substantially coplanar.

11. The semiconductor structure of claim 10, wherein a top surface of the capping layer is substantially coplanar with the back sides of the first semiconductor die and the insulating encapsulant.

12. The semiconductor structure of claim 1, wherein sidewalls of the second semiconductor die, the capping layer, and the insulating encapsulant are substantially coplanar.

13. A semiconductor structure, comprising:
a first semiconductor die comprising a first sidewall and a second sidewall laterally displaced from the first sidewall;
a second semiconductor die underlying and bonded to the first semiconductor die;
a capping layer conformally lining the first and second semiconductor dies to seal a bonding interface of the first and second semiconductor dies; and
an insulating encapsulant covering the first semiconductor die, the second semiconductor die, and the capping layer, the capping layer separating the insulating encapsulant from the first and second semiconductor dies.

14. The semiconductor structure of claim 13, wherein the first sidewall of the first semiconductor die is smoother than the second sidewall of the first semiconductor die.

15. The semiconductor structure of claim 13, wherein the first semiconductor die further comprises a third sidewall laterally displaced from the first and second sidewalls.

16. The semiconductor structure of claim 13, wherein the bonding interface of the first and second semiconductor dies is substantially flat.

17. A manufacturing method of a semiconductor structure, comprising:
bonding a first semiconductor die to a second semiconductor die, wherein the first semiconductor die comprises a first portion and a second portion connected to the first portion, and the first portion is wider than the second portion;
forming a capping layer to seal a bonding interface of the first and second semiconductor dies; and
forming an insulating encapsulant over the second semiconductor die to cover the first semiconductor die and the capping layer.

18. The manufacturing method of claim 17, wherein bonding the first semiconductor die to the second semiconductor die comprises:
forming dielectric-to-dielectric bonds and metal-to-metal bonds on the bonding interface of the first and second semiconductor dies, wherein the bonding interface is free of solder material.

19. The manufacturing method of claim 17, wherein forming the capping layer comprises:
conformally depositing a layer of capping material on the first and second semiconductor dies.

20. The manufacturing method of claim 17, wherein forming the insulating encapsulant comprises:
forming a layer of insulating material on the second semiconductor die to cover the first semiconductor die and the capping layer; and
performing a planarization process on the layer of insulating material, wherein after the planarization process, top surfaces of the insulating encapsulant, the capping layer, and the first semiconductor die are substantially leveled with one another.
